(19) United States
(12) Patent Application Publication
(10) Pub. No.: US 2024/0243167 A1
(43) Pub. Date: Jul. 18, 2024

(54) SUPER JUNCTION SEMICONDUCTOR DEVICE AND METHOD OF MANUFACTURING THE SAME

(71) Applicant: Magnachip Semiconductor, Ltd., Cheongju-si (KR)

(72) Inventors: Chanho PARK, Seoul (KR); Kihwan KIM, Seoul (KR); Jungyeon LEE, Seoul (KR); Suyoung MOON, Gwacheon-si (KR); Jiyong LIM, Seoul (KR)

(73) Assignee: Magnachip Semiconductor, Ltd., Cheongju-si (KR)

(21) Appl. No.: 18/411,252

(22) Filed: Jan. 12, 2024

(30) Foreign Application Priority Data
Jan. 13, 2023 (KR) 10-2023-0005588
Dec. 8, 2023 (KR) 10-2023-0177225

(51) Int. Cl. H01L 29/06; H01L 29/40; H01L 29/66; H01L 29/78; H01L 21/265; H01L 21/266

(52) U.S. Cl. CPC H01L 29/0634; H01L 29/402; H01L 29/66666; H01L 29/7827; H01L 21/26513; H01L 21/266

(57) ABSTRACT

A super junction semiconductor device includes a substrate, an active cell disposed on the substrate, an edge termination region surrounding the active cell, a peripheral region formed between the active cell and the edge termination region, a plurality of first conductivity type pillars and second conductivity type pillars alternately provided at an edge of the active cell and the peripheral region and the edge termination region, and a charge sharing region connecting the second conductivity type pillars in the peripheral region with the second conductivity type pillars in the edge termination region above the peripheral region and the edge termination region.

### CROSS REFERENCE TO RELATED APPLICATION

This application claims the benefit under 35 U.S.C. § 119(a) of Korean Patent Application No. 10-2023-0005588, filed Jan. 13, 2023, and Korean Patent Application No. 10-2023-0177225, filed Dec. 8, 2013, the entire disclosures of which are incorporated herein by reference for all purposes.

### BACKGROUND

### 1. Field

The following description relates to a super junction semiconductor device and a method of manufacturing the same, and more specifically, to a super junction semiconductor device that may secure a hole current path during reverse recovery when a reverse bias is applied by connecting a charge sharing region of a peripheral region and an edge termination region, and may stably secure a di/dt value, which is a slope value of a reverse recovery current, and a method of manufacturing the same.

### 2. Description of the Related Art

Among power semiconductor devices, a super junction MOSFET is a semiconductor device that can obtain low ON resistance and high breakdown voltage by forming vertically alternating a N-pillar or N-drift region and a P-pillar region in an epitaxial layer formed on a substrate.

The super junction MOSFET device may be applied in various applications such as DC-DC converters, inverters, LLC converters, and etc. which are power supply devices. To be applied in such applications, it is necessary to secure the robustness and ruggedness of the di/dt value, which is a slope value of a reverse recovery current of a body diode inside the device, and to secure the breakdown voltage, ON resistance, and forward voltage characteristics. When the slope value of the reverse recovery current of the diode is not secured, the high reverse voltage and reverse current during a reverse recovery operation of the body diode formed in the super junction MOSFET device may cause the device to break down and cause problems with the reliability of the device.

The super junction MOSFET device comprises an active cell, an edge termination region, and a peripheral region disposed between the active cell and the edge termination region. In particular, the phenomenon of burnt marks caused by device breakdown occurs most often in the peripheral region of the corner region, which is the end of the super junction MOSFET device, due to the concentration of the hole current near the corner of the peripheral region. To prevent this, in the related art, there are methods of further implementing a Schottky diode to reduce the hole carriers, or methods of further performing helium irradiation or electron beam irradiation to reduce the hole carrier lifetime, but these methods not only affect the device characteristics due to an increase in leakage current or ON-state current, but also the process cost.

To prevent this phenomenon, it is very important to optimize the hole current path during reverse recovery to improve the robustness and ruggedness of the slope value of the reverse recovery current of the body diode in the peripheral region and edge termination region placed in the super junction MOSFET device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. To solve the aforementioned problems, various embodiments of the present disclosure are directed to securing a hole current path during reverse recovery and securing a di/dt value, which is a slope value of a reverse recovery current, when a reverse bias is applied by connecting charge sharing regions in a peripheral region and an edge termination region.

The effects that may be obtained by the present disclosure are not limited to the aforementioned effects described above and other technical effects not described above will be apparent to one having ordinary skill in the art to which the present disclosure pertains from the following description.

In one general aspect, a super junction semiconductor device includes a substrate, an active cell disposed on the substrate, an edge termination region surrounding the active cell, a peripheral region formed between the active cell and the edge termination region, a plurality of first conductivity type pillars and second conductivity type pillars alternately provided at an edge of the active cell and the peripheral region and the edge termination region, and a charge sharing region connecting the second conductivity type pillars in the peripheral region with the second conductivity type pillars in the edge termination region above the peripheral region and the edge termination region.

The charge sharing region may include a peripheral charge sharing region disposed in the peripheral region and an edge termination charge sharing region disposed in the edge termination region.

The super junction semiconductor device may further include a body region of the second conductivity type formed on each of the second conductivity type pillars provided at the edge of the active cell.

The super junction semiconductor device may further include source regions of the first conductivity type formed in the body region of the second conductivity type, and a body contact region of the second conductivity type formed between the source regions of the first conductivity type.

The super junction semiconductor device may further include at least one pillar of the second conductivity type provided at an outermost portion of the edge termination region and not connected to the charge sharing region.

The super junction semiconductor device may further include a field oxide film formed on the charge sharing region in the edge termination region, and a gate insulating film formed on the source regions and the plurality of first conductivity type pillars in the active cell, an end portion and a side surface of the field oxide film toward the peripheral region, and the charge sharing region at an edge of the peripheral region.

The super junction semiconductor device may further include a gate electrode formed on the gate insulating film in the active cell, and a field plate formed on the gate insulating film formed over the peripheral region and the edge termination region.

The super junction semiconductor device may further include a first insulating film formed on side surfaces and an upper surface of the gate electrode, the field plate, and the field oxide film, and a second insulating film formed on the first insulating film.

The super junction semiconductor device may further include a gate runner formed on the field plate and connected to the field plate.

The super junction semiconductor device may further include a peripheral contact region formed in the peripheral charge sharing region disposed in the peripheral region.

The super junction semiconductor device may further include a source electrode formed on a body contact region formed between source regions of the active cell and the peripheral contact region of the peripheral region, and a drain electrode formed under the substrate.

A length of a cross-sectional area of the peripheral contact region may be determined according to a preset ratio based on a length of a cross-sectional area of the charge sharing region in the peripheral region.

When the super junction semiconductor device is viewed from above, an area where an upper surface and a lower surface of the peripheral region and side surfaces of the peripheral region meet may be defined as a peripheral corner region, and an area of the charge sharing region in the peripheral corner region may be determined according to a preset ratio based on an area of the peripheral corner region.

A second conductivity type concentration may increase at a point where the peripheral charge sharing region meets the edge termination charge sharing region and may diffuse further toward the second conductivity type pillars.

A depth of the peripheral charge sharing region may be greater than a depth of the edge termination charge sharing region.

A length of a cross-sectional area of the peripheral contact region may account for 30 to 60% of a length of a cross-sectional area of the peripheral charge sharing region.

An area of the charge sharing region in the peripheral corner region may account for 30 to 80% of the area of the peripheral corner region.

A horizontal length of the charge sharing region in the peripheral corner region may account for 20 to 50% of a horizontal length of the peripheral corner region.

The charge sharing region in the peripheral corner region may be disposed in contact with a surface of an epitaxial layer.

In another general aspect, a method of manufacturing a super junction semiconductor device includes forming an epitaxial layer in which first conductivity type pillars and second conductivity type pillars are alternately formed at an edge of an active cell and in a peripheral region and an edge termination region of a semiconductor substrate, forming an edge termination charge sharing region connecting the second conductivity type pillars formed above the epitaxial layer in the edge termination region, forming a field oxide film on the edge termination charge sharing region and the epitaxial layer in the edge termination region, forming a gate insulating film on both ends of the field oxide film and on the first conductivity type pillars in the active cell, forming a gate electrode on the gate insulating film in the active cell and forming a field plate on the gate insulating film in the edge termination region, forming a body region on the second conductivity type pillars in the active cell, forming a peripheral charge sharing region connecting the second conductivity type pillars formed above the epitaxial layer in the peripheral region, forming source regions in both ends of an upper portion of the body region, forming a first insulating film over an entire region of the semiconductor substrate, forming a body contact region between the source regions in the body region and forming a peripheral contact region on top of the peripheral charge sharing region, forming a second insulating film on the first insulating film, forming a source electrode connected to the body contact region and the peripheral contact region, and forming a gate runner connected to the field plate, and forming a drain electrode under the semiconductor substrate.

The forming of the epitaxial layer may include forming a first epitaxial layer having a predetermined height on the semiconductor substrate at the edge of the active cell and in the peripheral region and the edge termination region, implanting second conductivity type ions into a portion in which the second conductivity type pillars are formed above the first epitaxial layer, diffusing the second conductivity type ions while forming a second epitaxial layer on the first epitaxial layer, and implanting the second conductivity type ions into a portion in which the second conductivity type pillars are formed above the second epitaxial layer.

The method may further include forming a source contact region on the source regions.

The method may further include forming a source electrode connected to the body contact region, the source contact region, and the peripheral contact region, and forming a drain electrode beneath the substrate.

The first insulating film may be formed on side surfaces and an upper surface of the gate electrode, the field plate, and the field oxide film.

When the super junction semiconductor device is viewed from above, an area where an upper surface and a lower surface of the peripheral region and side surfaces of the peripheral region meet may be defined as a peripheral corner region, the forming of the peripheral charge sharing region may further include determining an area of the charge sharing region in the peripheral corner region according to a preset ratio based on an area of the peripheral corner region.

The forming of the edge termination charge sharing region may further include forming an edge charge sharing region mask on the epitaxial layer, forming a plurality of openings by patterning the edge charge sharing region using the edge charge sharing region mask, and forming a second conductivity type edge charge sharing ion implantation layer on the plurality of openings, and a width of the second conductivity type edge charge sharing ion implantation layer may gradually increase from the edge termination region toward the peripheral region. The effects that may be obtained by the present disclosure are not limited to the aforementioned effects described above, and other technical effects not described above will be apparent to one having ordinary skill in the art to which the present disclosure pertains from the following description.

### BRIEF DESCRIPTION OF THE DRAWINGS

FIG. 1 illustrates a plan view of a super junction semiconductor device according to one or more examples of the present disclosure.

FIG. 2 illustrates an enlarged plan view illustrating one portion of the super junction semiconductor device according to one or more examples of the present disclosure.

FIGS. 3A and 3B illustrate cross-sectional views illustrating an X-X′ cross section of the super junction semiconductor device illustrated in FIG. 2.

FIGS. 4 to 17 illustrate cross-sectional views illustrating a series of processes of a method of manufacturing the super junction semiconductor device according to one or more examples of the present disclosure. Other features and aspects will be apparent from the following detailed description, the drawings, and the claims.

### DETAILED DESCRIPTION

Advantages and features of the present disclosure and methods for achieving them will become clear with reference to embodiments described below in detail in conjunction with the accompanying drawings. However, the present disclosure is not limited to the embodiments disclosed below but can be implemented in various different forms, these embodiments are merely provided to make the disclosure of the present disclosure complete and fully inform those skilled in the art to which the present disclosure pertains of the scope of the present disclosure, and the present disclosure is only defined by the scope of the appended claims. The same reference number indicates the same components throughout the specification.

When a first component is “connected to” or “coupled to” a second component, it includes both a case in which the first component is directly connected or coupled to the second component or a case in which other components are interposed therebetween. On the other hand, when the first component is “directly connected to” or “directly coupled to” the second component, it means that other components are not interposed therebetween. The term “and/or” includes each of stated items and any combination of one or more.

Terms used in the specification are for describing the embodiments and are not intended to limit the present disclosure. In the specification, the singular form also includes the plural form unless specifically stated in the phrase. As used herein, “comprises” and/or “comprising” means that the stated component, step, operation, and/or element do not preclude the presence of addition of one or more other components, steps, operations, and/or elements.

Although first, second, and the like are used to describe various components, it goes without saying that these components are not limited by these terms. These terms are only used to distinguish one component from another component.

Therefore, it goes without saying that a first component to be described below may be a second component within the technical spirit of the present disclosure. Unless otherwise defined, all terms (including technical and scientific terms) used in the specification may be used as meaning commonly understood by those skilled in the art to which the present disclosure pertains. In addition, terms defined in commonly used dictionaries are not construed ideally or excessively unless clearly and specially defined.

The term “unit” or “module” used in the present embodiment is software or a hardware component such as a field programmable gate array (FPGA) or an application specific integrated circuit (ASIC), and the “unit” or “module” performs certain functions. However, the “unit” or “module” is not limited to software or hardware. The “unit” or “module” may be configured to be disposed in an addressable storage medium and configured to play one or more processors. Therefore, as an example, the “unit” or “module” is components such as software components, object-oriented software components, class components, and task components, processes, functions, properties, procedures, subroutines, segments of program code, drivers, firmware, microcode, circuitry, data, databases, data structures, tables, arrays, and variables. Functions provided in components and “units” or “modules” may be combined into the smaller number of components and “unit” or “modules” or separated into additional components and “units” or “modules.”

Operations of a method or algorithm described in connection with some embodiments of the present disclosure may be implemented directly in hardware and software modules executed by a processor or a combination of the two. The software modules may reside in a RAM memory, a flash memory, a ROM memory, an EPROM memory, an EEPROM memory, a register, a hard disk, a removable disk, a CD-ROM, or any other form of recording medium known in the art. An exemplary recording medium is coupled to a processor, and the processor may read information from the recording medium and write the information to the storage medium. As another method, the recording medium may be integrated with the processor. The processor and the recording medium may reside in an ASIC. The ASIC may reside in a user terminal.

Hereinafter, embodiments of the present disclosure will be described in detail with reference to the accompanying drawings so that those skilled in the art to which the present disclosure pertains may easily carry out the present disclosure. However, the present disclosure may be implemented in various different forms and is not limited to embodiments described herein.

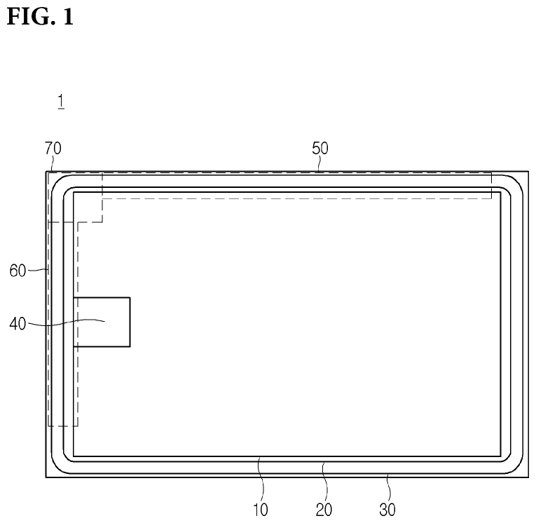

FIG. 1 illustrates a plan view of a super junction semiconductor device according to one or more examples of the present disclosure.

Referring to FIG. 1, a super junction semiconductor device 1 may include an active cell 10, an edge termination region 30, and a peripheral region 20. A cell region, which is the active cell 10, may be formed at a central side of the super junction semiconductor device 1, and the super junction semiconductor device 1 may include the edge termination region 30 surrounding the active cell 10 and the peripheral region 20 disposed between the active cell 10 and the edge termination region 30.

A gate pad 40 may be formed on a central portion of the active cell 10.

The edge termination region 30 and the peripheral region 20 may be divided according to each position. The edge termination region 30 and the peripheral region 20 may be divided into an edge/peripheral top and bottom region 50 disposed at top and bottom sides of the active cell 10, an edge/peripheral side region 60 disposed on both side surfaces of the active cell 10, and an edge/peripheral corner region 70 connecting the edge/peripheral top and bottom region 50 to the edge/peripheral side region 60 with respect to the active cell 10.

A charge sharing region may be formed in the edge termination region 30 and the peripheral region 20. The charge sharing region may be formed in a ring shape in the edge termination region 30 and may have the characteristic that may be formed only in some regions in the peripheral region 20.

When a reverse bias is applied, a current may be concentrated locally in the edge termination region 30 and the peripheral region 20 positioned near the corner region, and in this case, in order to protect the device, it is very important to secure a current movement path and a di/dt value, which is a slope value of the reverse recovery current.

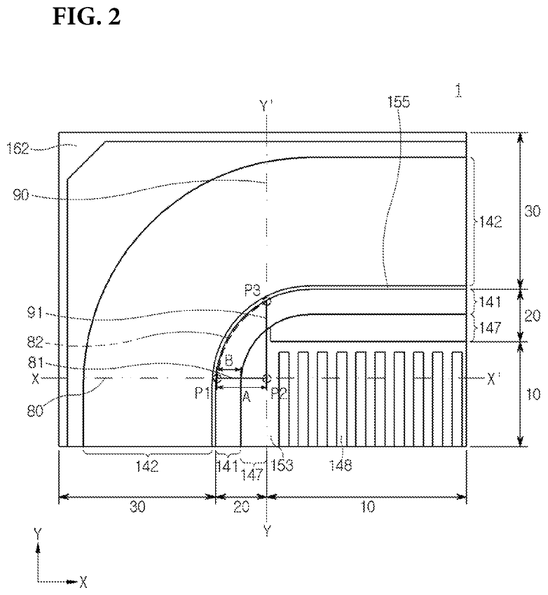

Increasing and securing an area of the charge sharing region will be described below with reference to FIG. 2, which is an enlarged view of one portion of the edge/peripheral corner region 70.

FIG. 2 illustrates an enlarged plan view illustrating one portion of the super junction semiconductor device according to one or more examples of the present disclosure. FIG. 2 is an enlarged plan view illustrating one portions of top and bottom regions and side regions of the edge termination and peripheral regions of the super junction semiconductor device according to one example of the present disclosure.

Referring to FIG. 2, the super junction semiconductor device 1 may be divided into the active cell 10, the edge termination region 30, and the peripheral region 20 disposed between the active cell 10 and the edge termination region 30.

The edge termination region 30 may include a guard ring region 162 (also referred to as a floating electrode), an edge termination charge sharing region 142, and a field plate 155. A gate runner may be formed on the field plate 155, and the gate runner may be connected to the gate pad 40.

The peripheral region 20 may include a peripheral charge sharing region 141 and a peripheral contact region 147. A source electrode may be formed on the peripheral contact region 147. The peripheral contact region 147 may be connected to a source contact region 148 disposed in the active cell 10 via a source electrode.

The charge sharing regions 141 and 142 may be formed in portions of the peripheral region 20 and the edge termination region 30. The charge sharing regions 141 and 142 may be divided into the peripheral charge sharing region 141 formed in the peripheral region 20 and the edge termination charge sharing region 142 formed in the edge termination region 30. For the charge sharing regions 141 and 142, the charge sharing regions 141 and 142 may be formed by arranging a mask on an epitaxial layer, exposing the epitaxial layer through a mask etching process with respect to portions on which the charge sharing regions 141 and 142 are formed, and performing an ion implantation process on the exposed epitaxial layer.

A plurality of pillar regions may be formed under a gate electrode 153 and the source contact region 148.

The edge termination region 30 may include the guard ring region (floating electrode 162), the edge termination charge sharing region 142, and the field plate 155. The peripheral region 20 may include the peripheral charge sharing region 141 and the peripheral contact region 147. The active cell 10 may be disposed by being surrounded by the peripheral region 20 and the edge termination region 30.

The charge sharing regions 141 and 142 may be formed to extend from the edge termination region 30 to the peripheral region 20. When areas of the charge sharing regions 141 and 142 increase toward the peripheral region 20, it is possible to secure a hole current path and secure the robustness and ruggedness of a di/dt value, which is a slope value of a reverse recovery current, when a reverse bias is applied to the super junction semiconductor device 1 or a reverse recovery operation is performed, thereby implementing a stable operation of the super junction semiconductor device 1.

The peripheral region 20 is a transition region electrically connecting the edge termination region 30 to the active cell 10 and may function as a buffer of the edge termination region 30 during the reverse recovery operation. The reverse current or the hole current may enter a drain region through the peripheral charge sharing region 141 in the peripheral region 20 to secure the stable reverse recovery operation and the slope value of the reverse recovery current. Therefore, it is important to increase the area of the peripheral charge sharing region 141 in the peripheral region 20.

However, when the areas of the charge sharing regions 141 and 142 are increased to a predetermined level or more, the slope value of the reverse recovery current may be further increased during the reverse recovery operation, but since a P-type concentration, which is a concentration of the second conductivity type impurity ions of the charge sharing regions 141 and 142, is further increased, it may be difficult to secure a stable breakdown voltage due to the P-type concentration higher than an N-type concentration, which is a concentration of the first conductivity type impurity ions of the peripheral region 20 and the edge termination region 30. In other words, it is very important to secure the optimized areas of the charge sharing regions 141 and 142.

Virtual lines may be marked on the active cell 10, the peripheral region 20, and the edge termination region 30 in the corner region of the super junction semiconductor device 1. The virtual line indicates a first line 80 extending in an X-axis direction as X-X′, and a second line 90 extending in a Y-axis direction as Y-Y′. The second line 90 is a line extending to a Y-axis along an edge of the active cell 10. The first line 80 passes through points P1 and P2. Point P1 is positioned at a point where a slope of the straight field plate 155 starts to change into a curved shape at an edge of a border of the field plate 155 of the peripheral region 20. Point P2 is positioned at a point where the first line 80 and the second line 90 cross each other. Point P3 is positioned at a point where the peripheral region 20 and the edge termination region 30 meet on the second line 90.

A 1-1 line 81 may be one straight line connecting points P1 and P2. A 2-1 line 91 may be one straight line connecting points P2 and P3. A third line 82 may be one curve connected along the field plate 155 between points P1 and P3.

A region formed by connecting the 1-1 line 81, the 2-1 line 91, and the third line 82 may be referred to as a peripheral corner region. In addition, the total area of the peripheral corner region may be referred to as a peripheral corner region area. The peripheral corner region may include a corner charge sharing region. An area of the corner charge sharing region may account for about 30 to 80% of the peripheral corner region area. A ratio of these areas may be adjusted to an optimized ratio in order to maintain the breakdown voltage and improve the slope value of the reverse recovery current.

In addition, a horizontal length B of the corner charge sharing region on the 1-1 line 81 may account for about 20 to 50% of a horizontal length A of the peripheral corner region.

In addition, in order to secure a more stable slope value of the reverse recovery current, a contact resistance can be reduced in a range in which the characteristics of the breakdown voltage or the slope value of the reverse recovery current is not degraded by optimizing the area of the peripheral contact region 147 in which a portion of the source electrode is formed in the peripheral region 20.

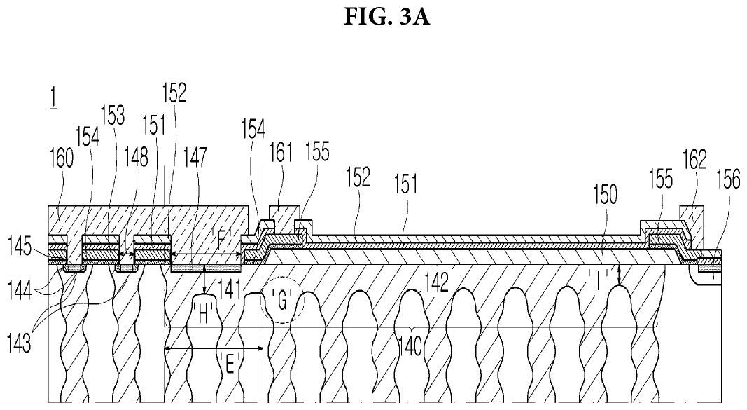

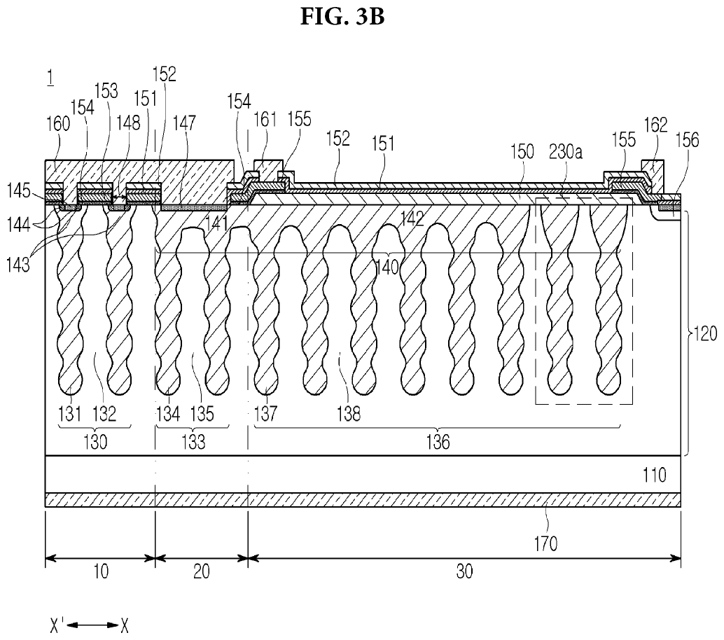

FIGS. 3A and 3B illustrate cross-sectional views illustrating an X-X′ cross section of the super junction semiconductor device illustrated in FIG. 2.

Referring to FIG. 3A, the super junction semiconductor device 1 may include the active cell 10, the peripheral region 20, and the edge termination region 30. An epitaxial layer 120 may be formed on a substrate 110 of the super junction semiconductor device 1, and a drain electrode 170 may be formed under the substrate 110.

The epitaxial layer 120 may be a region doped with the first conductivity type impurity. A plurality of pillar regions may be formed in the epitaxial layer 120. The pillar regions may be divided into a first pillar region 130 formed in the active cell 10, a second pillar region 133 formed in the peripheral region 20, and a third pillar region 136 formed in the edge termination region 30.

The first pillar region 130 may include a plurality of first first conductivity type (N-type) pillars (N-pillars) 132 and first second conductivity type (P-type) pillars (P-pillars) 131. The first P-pillar 131 may be formed between the first N-pillars 132. A second conductivity type body region 143 may be formed on an upper layer of the first P-pillar 131. The first P-pillar 131 and the body region 143 have a structure that may be connected. The first conductivity type source region 144 may be formed in the body region 143. The second conductivity type body contact region 145 may be formed between the source regions 144. The body contact region 145 may be formed on a surface of the epitaxial layer 120.

A gate insulating film 154 may be formed on the body region 143 and the first N-pillars 132 disposed in the active cell 10. The gate insulating film 154 may be formed on one region of the source region 144. The gate insulating film 154 may be formed on an end portion and a side surface of a field oxide film 150 toward the peripheral region 20 and on the peripheral charge sharing region 141 outside the peripheral region 20.

The gate electrode 153 may be formed on the gate insulating film 154. A first insulating film 151 may be formed on side surfaces and an upper surface of the gate electrode 153, and a second insulating film 152 may be formed on the first insulating film 151. The source electrode 160 may be formed on the body contact region 145 and may be in ohmic contact with the body contact region 145.

The second pillar region 133 in the peripheral region 20 may include a plurality of second first conductivity type N-type pillars 135 and second second conductivity type P-type pillars 134. The second P-pillar 134 may be formed between the second N-pillars 135.

The third pillar region 136 in the edge termination region 30 may include third first conductivity type N-type pillars 138 and third second conductivity type P-type pillars 137. The third P-pillar 137 may be formed between the third N-pillars 138.

The charge sharing region 140 may be formed on the surface of the epitaxial layer 120 of the peripheral region 20 and the edge termination region 30. The charge sharing region 140 may be formed of the second conductivity type impurity ions. The charge sharing region 142 in the edge termination region 30 and the charge sharing region 141 in the peripheral region 20 may each be formed via an ion implantation process and an annealing process, respectively. The charge sharing region 141 in the peripheral region 20 may be referred to as the peripheral charge sharing region 141, and the charge sharing region 142 in the edge termination region 30 may be referred to as the edge termination charge sharing region 142. The peripheral charge sharing region 141 and the edge termination charge sharing region 142 may be formed by connecting them. The peripheral charge sharing region 141, the second N-pillar 135, and the second P-pillar 134 may be connected, and the edge terminal charge sharing region 142, the third N-pillar 138, and the third P-pillar 137 may be connected.

After the edge termination charge sharing region 142 is formed, the body region 143 may be formed in the peripheral charge sharing region 141 and the active cell 10 at the same time. Thereafter, the peripheral charge sharing region 141 and the edge termination charge sharing region 142 may be formed into one charge sharing region 140 through a thermal diffusion process.

A second conductivity type concentration may increase at point G where the peripheral charge sharing region meets the edge termination charge sharing region and spreads further toward the second conductivity type pillars.

A depth “H” of the peripheral charge sharing region 141 may be formed to be greater than a depth “I” of the edge termination charge sharing region. Such a depth difference is caused to allow a hole current to exit to the peripheral contact region 147 by forming a concentration of the peripheral charge sharing region 141 to be higher than a concentration of the edge termination charge sharing region 142 to set the hole current path from the edge termination charge sharing region 142 to the peripheral charge sharing region 141.

In other words, the depth of the charge sharing region 142 in the edge termination region 30 may gradually decrease toward the guard ring region 162.

The body contact region 145 may be formed in the body region 143 of the active cell 10, and at the same time, a peripheral charge sharing contact region may be formed in the peripheral charge sharing region 141.

The peripheral contact region 147 may be formed on the peripheral charge sharing region 141 and the peripheral charge sharing contact region. In another example, the peripheral contact region 147 may be formed by contacting only the peripheral charge sharing contact region.

It is important to not only optimize the area or length of the charge sharing region formed in the peripheral region 20 but also optimize the length and area of the peripheral contact region 147 in order to improve the reverse recovery current characteristics. In other words, as a cross-sectional area of the peripheral contact region 147 increases, the contact resistance decreases, effectively eliminating the hole current that occurs when a reverse bias is applied, thereby stabilizing a di/dt value, a slope value of the reverse recovery current.

In an example, a length F of the cross-sectional area of the peripheral contact region 147 may account for about 30 to 60% of a length E of the cross-sectional area of the peripheral charge sharing region 141. In this case, by optimizing a ratio of the lengths of the cross-sectional areas of the peripheral charge sharing region 141 and the peripheral contact region 147, it is possible to secure the slope value of the reverse recovery current without deterioration of the breakdown voltage.

The source electrode 160 may be formed on the peripheral contact region 147 of the peripheral region 20, the body contact region 145, and the source contact region 148 of the active cell 10. The source electrode 160 may function as a metal plate.

The field oxide film 150 may be formed on the edge termination charge sharing region 142 in the edge termination region 30.

The field plate 155 may be formed on a sidewall of the field oxide film 150. The field plate 155 may be positioned on one end portion of the field oxide film 150 toward the peripheral region 20 and formed on the field oxide film 150 and the gate insulating film 154. The field plate 155 may function to mitigate an electric field.

A gate runner 161 may be formed on the field plate 155. The gate runner 161 may be formed at the same time as the source electrode 160 is formed. The gate runner 161 may be connected to the gate pad 40 along the line of the edge termination region 30.

The guard ring or floating electrode 162 may be formed on the end portion of the edge termination region 30.

An edge junction region 156 may be formed under the floating electrode 162. The edge junction region 156 may function as a channel stopper for stopping the electric field generated when a reverse bias is applied.

The edge junction region 156 may be formed of the same conductivity type as the body region 143.

The concentration of the edge termination charge sharing region 142 formed in the edge termination region 30 may be lower than the concentration of the peripheral charge sharing region 141, and the breakdown voltage can be improved by the charge balance with the third N-pillar 135 in contact with the edge termination charge sharing region 142.

The edge termination charge sharing region 142 and the peripheral charge sharing region 141 may be connected, and may be disposed on the surface of the epitaxial layer 120. The charge sharing regions 141 and 142 formed in the edge termination region 30 and the peripheral region 20 may be referred to as “P-buried region (PBR)” or “P-top layer region.”

The charge sharing regions 141 and 142 disposed in the edge termination region 30 and the peripheral region 20 may be connected and formed in contact with the surface of the epitaxial layer 120. Therefore, it is possible to prevent the stress caused by the electric field induced by the high breakdown voltage when the device is turned off and a phenomenon in which a high lattice temperature is locally concentrated on the surface of the epitaxial layer 120, and prevent damage to the field oxide film 150 formed on the upper epitaxial layer 120 of the edge termination region 30 caused by the high electric field.

Referring to FIG. 3B, a structure of the super junction semiconductor device 1 according to another example of FIG. 3B is the same as the structure of the super junction semiconductor device 1 of FIG. 3A, but a portion 230a of the edge termination charge sharing region 142 may not be connected to another edge termination charge sharing region 142 in high-voltage applications requiring a high breakdown voltage. That is, the portion 230a formed near the outermost portion of the edge termination charge sharing region 142 formed on the plurality of third second conductivity type P-pillars 137 in the edge termination region 30 may not be connected to another edge termination charge sharing region 142. This region may be referred to as the edge charge pillar separation region 230a. In this case, the breakdown voltage may be further increased, but the slope value of the reverse recovery current may be reduced.

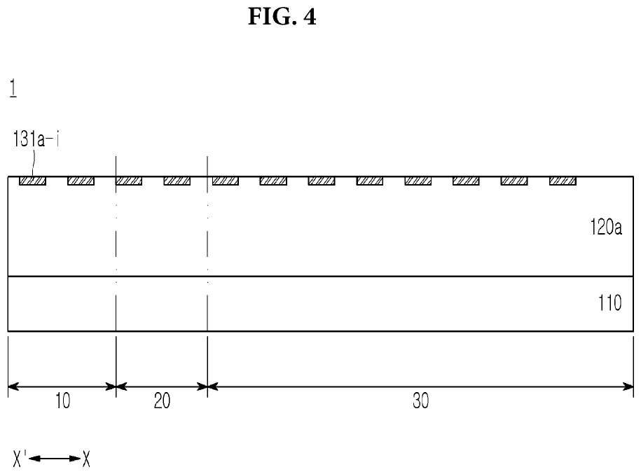

FIGS. 4 to 17 illustrate cross-sectional views illustrating a series of processes of a method of manufacturing the super junction semiconductor device according to one or more examples of the present disclosure.

Referring to FIG. 4, the active cell 10, the peripheral region 20, and the edge termination region 30 may be disposed in the substrate 110.

A multi epitaxial process, which is a process of forming a plurality of epitaxial layers, may be performed on the substrate 110.

First, a first epitaxial layer 120a may be formed on the substrate 110. The first epitaxial layer 120a may be formed in a thickness of 15 to 30 um.

The substrate 110 is an N-type doped semiconductor substrate 110, and the first epitaxial layer 120a may also include the N-type doped epitaxial layer 120a. The N-type doped epitaxial layer 120a may be formed by using a material such as PH3 (phosphine) and AsH3 (arsine) through an epi process.

The first epitaxial layer 120a may be further doped with the first conductivity type (e.g., the N-type), which may be referred to as a N-type blanket ion implantation process. By implanting ions on the first epitaxial layer 120a according to the N-type blanket ion implantation process, the concentration of the N-type conductivity type ion of the surface of the first epitaxial layer 120a may be increased.

Then, a first mask (not illustrated) may be disposed on the first epitaxial layer 120a. The first mask may be patterned to expose a portion of the first epitaxial layer 120a into which the second conductivity type (e.g., the P-type) ions are implanted. After the first implant layer 131a-i is formed by implanting the P-type ions into the exposed portion of the first epitaxial layer 120, the first mask may be removed.

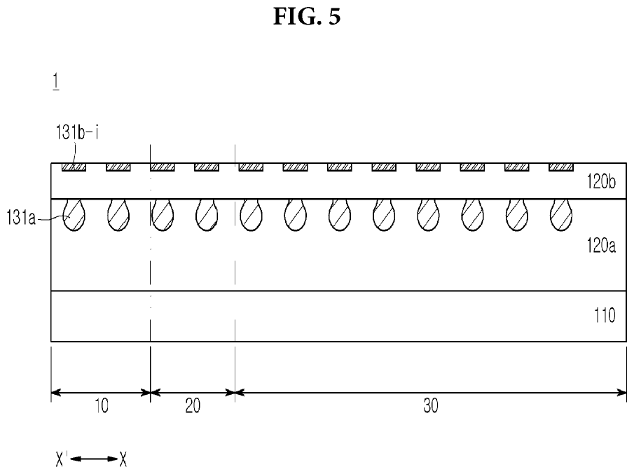

Referring to FIG. 5, a second epitaxial layer 120b may be formed on the first epitaxial layer 120a. The epitaxial process to form the second epitaxial layer 120b may include a high temperature annealing process. Due to the annealing process used in the epitaxial process to form the second epitaxial layer 120b, the first implant layer 131a-i may diffuse to form a second conductivity type first pillar layer 131a. In the process of diffusion of the first implant layer 131a-i, the diffusion of the second conductivity type pillar ions in the left and right directions may be reduced and the diffusion in the vertical direction may be increased by the N-type blanket ions located between the second conductivity type pillar ion implant layers to form a vertical pillar structure. Therefore, it is possible to improve the required breakdown voltage characteristics.

When the second epitaxial layer 120b is formed, the process temperature may be in a range of about 900 to 1300° C. The second epitaxial layer 120b may be formed in a thickness that is equal to or smaller than a thickness of the first epitaxial layer 120a. After the second epitaxial layer 120b is formed, the first conductivity type (e.g., the N-type) blanket ion implantation process may be performed.

Then, a second mask (not illustrated) may be disposed on the second epitaxial layer 120b. The second mask may be patterned to expose a portion of the second epitaxial layer 120b into which the second conductivity type ions are implanted. After a second implant layer 131b-i is formed by performing a P-type ion implantation process on the exposed mask pattern of the second epitaxial layer 120b, the second mask may be removed.

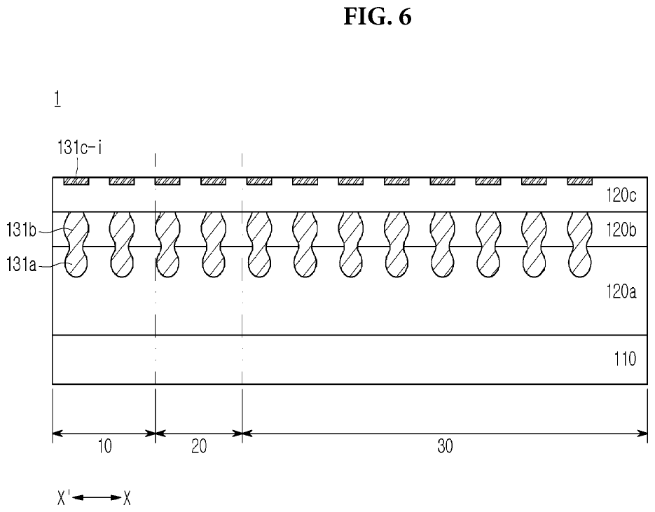

Referring to FIG. 6, a third epitaxial layer 120c may be formed on the second epitaxial layer 120b. The epi process of forming the third epitaxial layer 120c may include a high temperature annealing process. In the epi process of forming the third epitaxial layer 120c, the second implant layer 131b-i may be diffused to form a second conductivity type second pillar layer 131b. The second conductivity type first pillar layer 131a and second pillar layer 131b may be connected by diffusion.

The third epitaxial layer 120c may be formed with a thickness equal to or less than a thickness of the second epitaxial layer 120b. After the third epitaxial layer 120c is formed, the first conductivity type (e.g., the N-type) blanket ion implantation process may be performed.

Then, a third mask (not shown) may be disposed on the third epitaxial layer 120c. The third mask may be patterned to expose a portion of the third epitaxial layer 120c where the second conductivity type ions are implanted. After a third implant layer 131c-i is formed by performing a P-type ion implantation process on the exposed mask pattern of the third epitaxial layer 120c, the third mask may be removed.

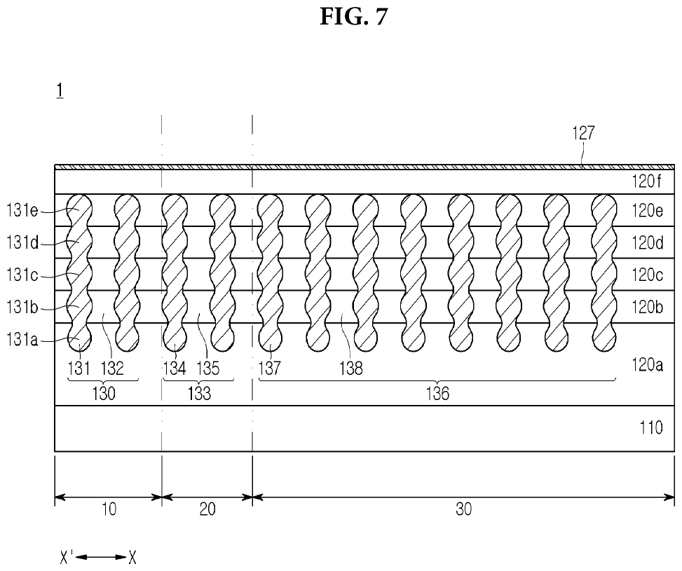

Referring to FIG. 7, by repeatedly performing the process described with reference to FIGS. 5 and 6, fourth to sixth epitaxial layers 120d to 120f may be formed to be stacked, and second conductivity type third to fifth pillar layers 131c to 131e may be formed. The second conductivity type first to fifth pillar layers 131a to 131e may be connected into a vertical pillar by diffusion.

The first to fifth pillar layers 131a to 131e formed in the active cell 10 may be referred to as the first P-pillar 131 in the first pillar region 130. The first N-pillar 132 may be formed between the plurality of P-pillars 131. The first to fifth pillar layers formed in the peripheral region 20 may be referred to as the second P-pillar 134 in the second pillar region 133. The second N-pillar 135 may be formed between the plurality of second P-pillars 134. The first to fifth pillar layers formed in the edge termination region 30 may be referred to as the third P-pillar 137 in the third pillar region 136. The third N-pillar 138 may be disposed between the plurality of third P-pillars 137. The first to third N-type pillar 132 to 138 may correspond to a portion of the epitaxial layer 120 that are not implanted with P-type ions.

The sixth epitaxial layer 120f may be formed with a thickness less than a thickness of the fifth epitaxial layer 120e. After the sixth epitaxial layer 120f is formed, a cleaning operation may be performed with hydrofluoric acid (HF) to remove naturally formed oxides. After the cleaning operation, a sacrificial oxide film 127 may be formed to recover a rough surface to a flat surface. Then, the N-type blanket ion implantation process may be additionally performed. Alternatively, after the sixth epitaxial layer 120f is formed and the N-type blanket ion implantation process is performed, the cleaning operation may be performed and the sacrificial oxide film 127 may be formed. The sacrificial oxide film 127 may be removed after damage or unevenness occurring on the surface of the epitaxial layer 120 is recovered.

According to another example, the epitaxial layer 120 and the pillar layer may be stacked higher. In particular, in devices that require a high breakdown voltage, 10 or more pillar layers may be stacked.

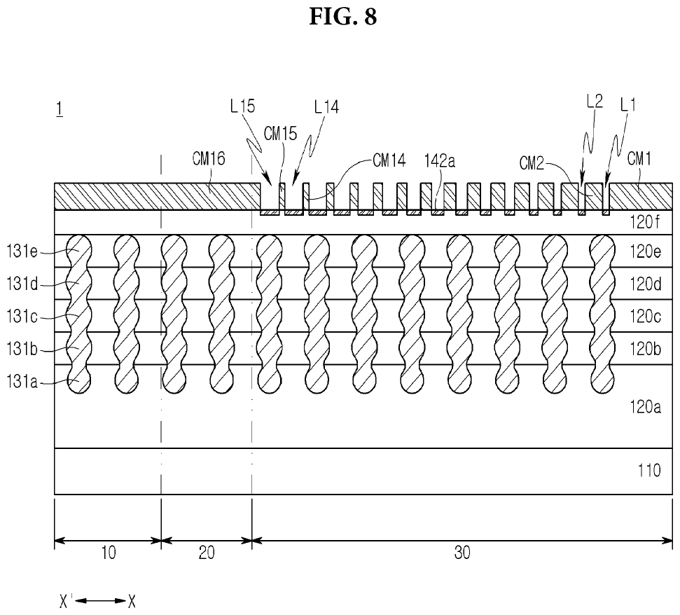

Referring to FIG. 8, an ion implantation process may be performed to form the edge termination charge sharing region 142 in the edge termination region 30.

Edge charge sharing masks CM1 to CM16 may be disposed on the sixth epitaxial layer 120f. A plurality of openings L1 to L15 may be patterned in the edge charge sharing masks CM1 to CM16 to implant the second conductivity type ions for forming the edge termination charge sharing region 142.

The plurality of openings L1 to L15 of the edge charge sharing masks CM1 to CM16 may be formed adjacent to an upper layer of the third P-type pillar 137. An edge termination charge sharing ion implantation layer 142a may be formed by implanting the second conductivity type ions into the openings L1 to L15 of the edge charge sharing mask. The edge termination charge sharing ion implantation layer 142a may be separately formed by implanting the second conductivity type ions into each of the openings L1 to L15 of the edge charge sharing mask.

A concentration of the edge termination charge sharing ion implantation layer 142a may be equal to or lower than a concentration of the fifth pillar layer 131e.

The edge terminal charge sharing ion implantation layer 142a may be formed to have a different width according to widths of the opening L1 to L15 of the edge charge sharing masks. The width of the edge termination charge sharing ion implantation layer 142a may gradually increase from the edge termination region 30 toward the peripheral region 20.

When the amount of P-type charge near the edge is large, the electric field does not expand, and thus the electric field is concentrated on the surface side of the epitaxial layer 120, which can lead to destruction of the surface side. Therefore, the electric field may be expanded near the edge by narrowing the width of the edge termination charge sharing ion implantation layers 142a located near the outermost edge. In other words, it is important to expand the electric field to the guard ring region (floating electrode 162) by balancing the P-type charge amount and the N-type charge amount of the edge termination charge sharing region 142, and when balanced, an optimized breakdown voltage can be obtained.

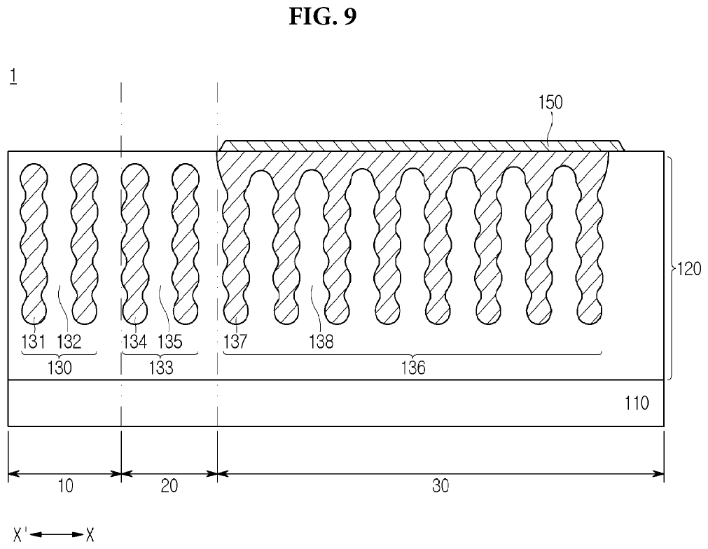

Referring to FIG. 9, an annealing process may be performed to diffuse the second conductivity type ions of the edge termination charge sharing ion implantation layer to form the edge termination charge sharing region 142. The edge termination charge sharing region 142 may be formed by diffusing to the surface of the epitaxial layer 120 via thermal diffusion, and contacting or bonding with the surface side. Additionally, the edge termination charge sharing region 142 may be formed by being connected to an upper layer of the third P-pillar 137 of the third pillar region 136 formed in the edge termination region 30.

In another example, as described above with reference to FIG. 3B, the concentration of the edge termination charge sharing region 142 formed in the edge termination region 30 may gradually decrease toward the guard ring region (floating electrode) to separate the previously formed edge termination charge sharing region 142 and form a separate edge termination charge sharing region. The separated edge termination charge sharing region may be referred to as an edge charge pillar separation region 230a. This may further increase the breakdown voltage by decreasing the concentration of the edge termination charge sharing region 142 in high voltage applications requiring a high breakdown voltage, but the slope value of the reverse recovery current may decrease due to the decreased concentration of the charge sharing region.

During the annealing process, a temperature may be in a range of about 1000 to 1300° C., and a time may be in a range of 100 to 200 minutes. This high-temperature annealing process may sufficiently diffuse the pillar regions formed below the edge termination charge sharing region 142 to form a more stable vertical pillar structure, resulting in a high breakdown voltage.

After the edge termination charge sharing region 142 is formed, the field oxide film 150 may be formed on the surface of the epitaxial layer 120. By performing patterning after a mask is disposed on the field oxide film 150, the field oxide film 150 of the remaining portion except for the edge termination charge sharing region 142 may be removed to form the field oxide film 150 on the edge termination charge sharing region 142. The field oxide film 150 may be formed via an oxidation process, and the oxide film material may include materials such as silicon oxide, silicon oxynitride, and silicon nitride.

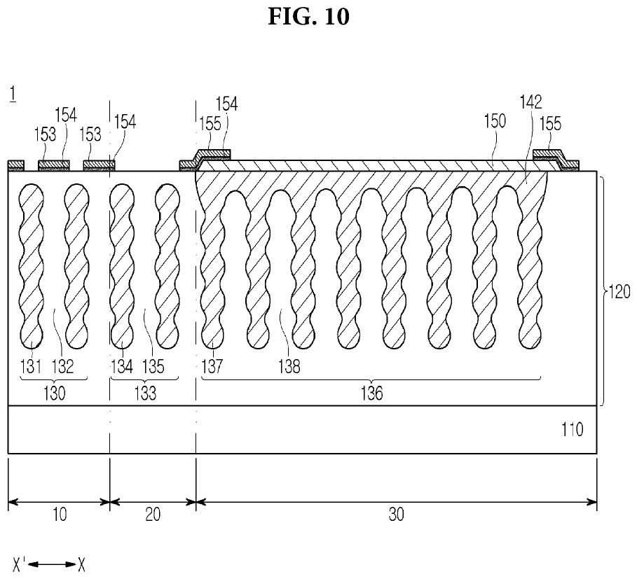

Referring to FIG. 10, the gate insulating film 154 may be formed on the field oxide film 150, and a polysilicon layer may be formed on the gate insulating film 154. The gate electrode 153 and the field plate 155 may be formed by etching the gate insulating film 154 and the polysilicon layer. When the polysilicon layer is deposited, a resistance of the gate electrode 153 may be reduced by additionally performing the ion implantation of phosphorus.

The field plate 155 may be formed on the field oxide film 150 and the gate insulating film 154 of the edge termination region 30. The field plate 155 may be formed on the side surfaces and the upper surfaces of the field oxide film 150 and the gate insulating film 154 positioned in the boundary region between the edge termination region 30 and the peripheral region 20. The gate electrode 153 may be formed on the gate insulating film 154 of the active cell 10.

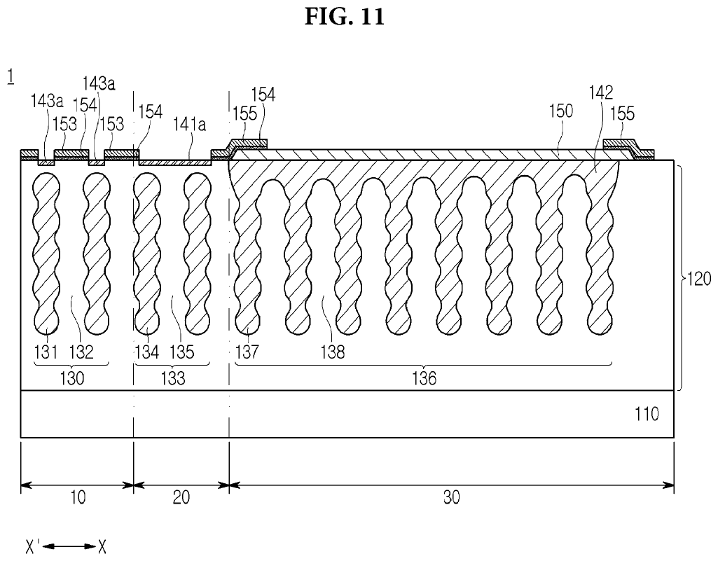

Referring to FIG. 11, the second conductivity type ion implantation process may be performed in the active cell 10 and the peripheral region 20. The second conductivity type ion implantation process may form the body region 143 in the active cell 10 and the peripheral charge sharing region 141 in the peripheral region 20 using the gate electrode 153 and the field plate 155 as a mask. The second conductivity type ion implantation process may be performed to form second conductivity type ion implantation layers 141a and 143a in the peripheral region 20 and the active cell 10. By using the gate electrode 153 and the field plate 155 as a mask, it is possible to simplify process operations and reduce process costs. The second conductive ion implantation process may be referred to as a P-well ion implantation process.

A concentration of the second conductivity type impurity ions used in the second conductivity type ion implantation process may be higher than a concentration of the second conductivity type impurity ions implanted in the edge termination charge sharing region 142.

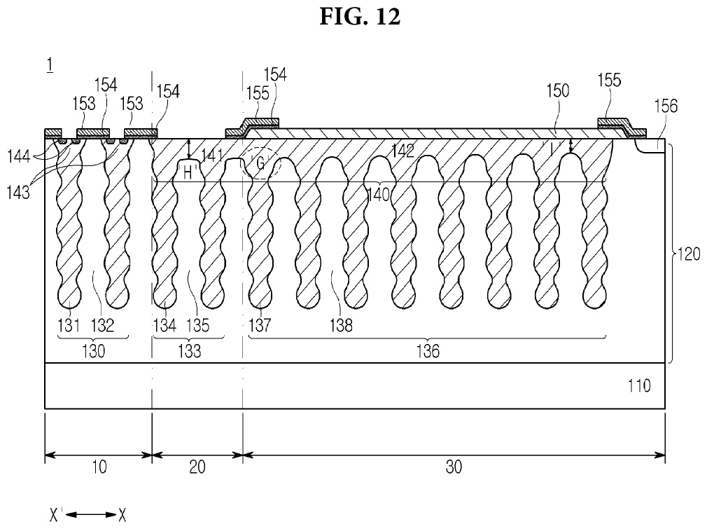

Referring to FIG. 12, the second conductivity type ion implantation layers 141a and 143a in the peripheral region 20 and the active cell 10 may be diffused via an annealing process to form the second conductivity type body region 143 and the second conductivity type peripheral charge sharing region 141.

The second conductivity type body region 143 in the active cell 10 may be diffused and connected to the first P-pillar 131 disposed beneath it.

The second conductivity type peripheral charge sharing region 141 in the peripheral region 20 may be diffused and connected to the second P-pillar 134 disposed below it. In addition, the peripheral charge sharing region 141 may be diffused and connected to the edge termination charge sharing region 142. The peripheral charge sharing region 141 and the edge termination charge sharing region 142 may be connected to both the second P-pillar 134 and the third P-pillar 137 disposed beneath them.

The second conductivity type concentration may increase at point G, where the peripheral charge sharing region meets the edge termination charge sharing region and diffuse further toward the pillar region.

During the annealing process, the process temperature may be in a range of about 900 to 1300° C.

The charge sharing region 140 may be referred to as “P-buried region (PBR)” or “P-top layer region.”

Only a portion on which the source region 144 is formed may be exposed by performing a patterning process after a mask is disposed between the gate electrodes 153 formed in the active cell 10, and the source region 144 may be formed by performing a source ion implantation process. The source region 144 may be formed by diffusion into some region below the gate electrode 153.

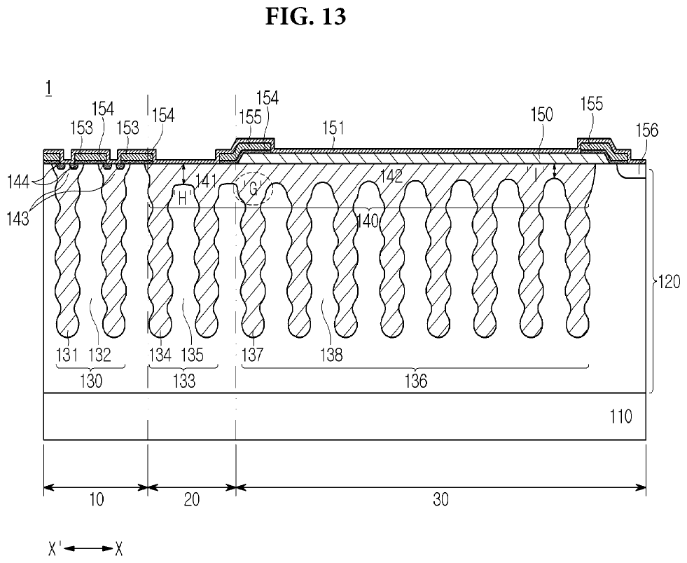

Referring to FIG. 13, the first insulating film 151 may be formed on the gate electrode 153, the field plate 155, and the field oxide film 150. The first insulating film 151 may be referred to as a spacer and made of materials such as silicon oxide (SiO₂), silicon nitride (SiN), silicon oxynitride (SiON), and nitride. The first insulating film 151 may be deposited with a thickness of about 800 to 2000 Å.

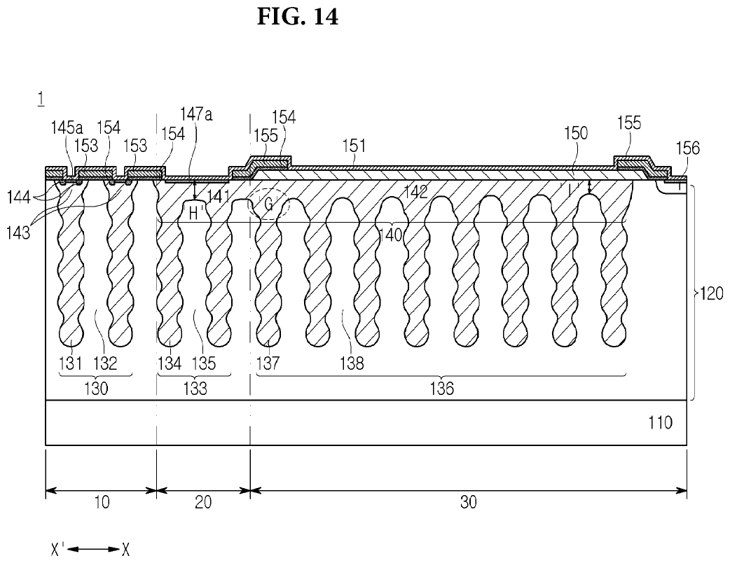

Referring to FIG. 14, a high-concentration second conductive blanket ion implantation process may be performed on the first insulating film 151 without arranging a separate mask. Therefore, a body contact ion implantation layer 145a may be formed in the active cell 10, and a peripheral charge sharing contact ion implantation layer 147a may be formed in the peripheral region 20.

Since the first insulating film 151 is formed thick on the source region 144 in the active cell 10, ions may not be implanted into the source region 144 when the second conductivity type blanket ion implantation process is performed. Conventionally, a separate mask is placed to block the source region 144, but in the present disclosure, after the first insulating film 151 is formed, a high-concentration second conductivity type blanket ion implantation process may be performed without placing a separate mask to protect the source region 144 to form the body contact ion implantation layer 145a, thereby simplifying process operation and reducing process costs.

A concentration of the body contact ion implantation layer 145a may be higher than the concentration of the peripheral charge sharing region 141.

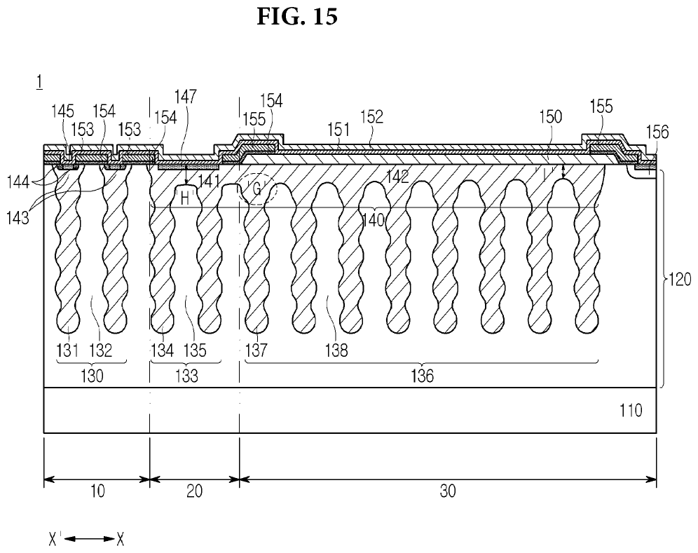

Referring to FIG. 15, the second insulating film 152 may be deposited on the first insulating film 151. After the second insulating film 152 is deposited, a thermal process may be performed to planarize the second insulating film 152. Due to the thermal process applied at this time, the body contact ion implantation layer may be formed as the second conductivity type body contact region 145, and the peripheral charge sharing contact ion implantation layer may be formed as the peripheral charge sharing contact region.

The second insulating film 152 may be formed of a boron-phosphors silicate glass (BPSG) or phosphors silicate glass (PSG) layer.

The second insulating film 152 may be deposited with a thickness of about 8000 to 12000 Å.

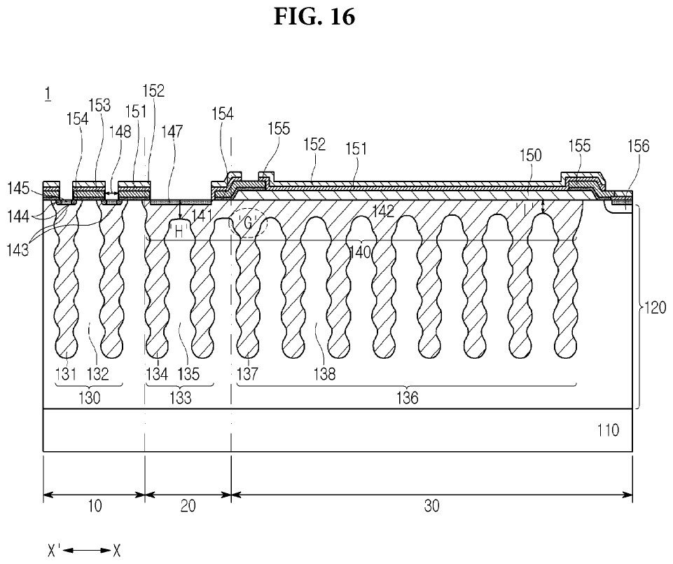

Referring to FIG. 16, by performing contact etching on the first insulating film 151 and the second insulating film 152, the source contact region 148, the peripheral contact region 147, and a gate runner contact region may be formed. A contact mask may be patterned after the contact mask is disposed on the first insulating film 151 and the second insulating film 152, and the contact regions may be exposed by etching the first insulating film 151 and the second insulating film 152. The body contact region 145 may be formed in the active cell 10. The peripheral contact region 147 may be formed in the peripheral region 20. The gate runner contact region may be formed on the field plate 155 of the edge termination region 30. The larger an area of the peripheral contact region 147, the larger a contact area, and thus the greater the resistance may be.

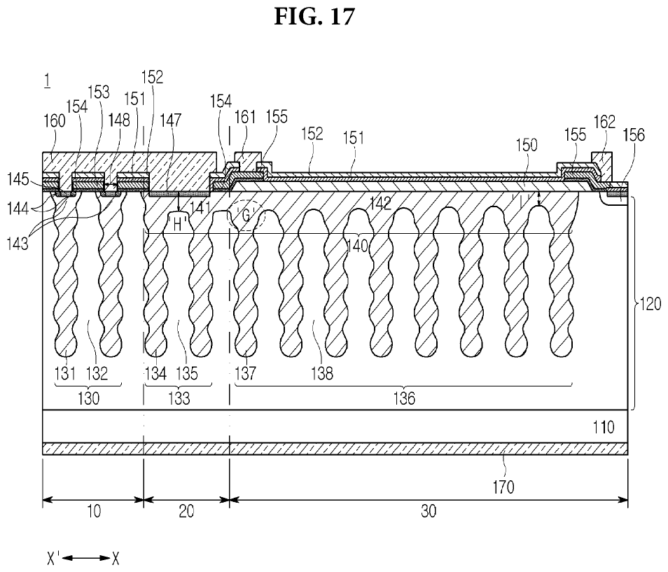

Referring to FIG. 17, a metal layer may be deposited on the etched contact regions. Then, the deposited metal layer may be planarized by performing a planarization process. The metal layer may be planarized via a chemical mechanical polishing (CMP) process. A metal etching process may be performed by arranging a mask on the planarized metal layer and patterning the metal layer. After the metal etching process, the source electrode 160 connected to the source contact region 148 and the peripheral contact region 147 may be formed. In addition, the gate runner 161 connected to the field plate 155 may be formed. In addition, the floating electrode 162 may be formed at an end of the edge termination region 30.

In the process of forming the metal layer, the metal layer may be formed by first depositing titanium (Ti) or titanium nitride, which functions as a metal barrier, depositing tungsten (W) in a contact hole, and depositing a layer of aluminum (Al) on the deposited layer.

Next, a back grinding process may be performed to reduce the thickness of the substrate 110 as a substrate 110 grinding process. The substrate 110 grinding process may reduce the resistance in the substrate 110 by reducing the thickness of the substrate 110.

Next, a lower metal layer may be formed. The lower metal layer may function as the drain electrode 170. The lower metal layer may be deposited with nickel/vanadium, silver, or the like.

By performing the above-described processes, a super junction semiconductor device 1 can be formed that is capable of securing an appropriate breakdown voltage and securing a slope value of the high reverse recovery current required when a reverse bias is applied.

According to one or more examples of the present disclosure, it is possible to provide the super junction semiconductor device for securing the hole current path during reverse recovery and securing the di/dt value, which is the slope value of the reverse recovery current, when the reverse bias is applied by connecting the charge sharing regions in the peripheral region and the edge termination region.

The effects obtainable from the present disclosure are not limited to the above-described effects, and other effects that are not mentioned will be able to be clearly understood by those skilled in the art to which the present disclosure pertains from the above description.

Although the present disclosure has been described with reference to the examples illustrated in the drawings, these are merely illustrative, and those skilled in the art will understand that various modifications and other equivalent embodiments are possible therefrom. Therefore, the true technical scope of the present disclosure should be determined by the technical spirit of the appended claims.

What is claimed is:

1. A super junction semiconductor device comprising:
a substrate;
an active cell disposed on the substrate;
an edge termination region surrounding the active cell;
a peripheral region formed between the active cell and the edge termination region;
a plurality of first conductivity type pillars and second conductivity type pillars alternately provided at an edge of the active cell and the peripheral region and the edge termination region; and
a charge sharing region connecting the second conductivity type pillars in the peripheral region with the second conductivity type pillars in the edge termination region above the peripheral region and the edge termination region.

2. The super junction semiconductor device according to claim 1, wherein the charge sharing region comprises a peripheral charge sharing region disposed in the peripheral region and an edge termination charge sharing region disposed in the edge termination region.

3. The super junction semiconductor device according to claim 1, further comprising:
a body region of the second conductivity type formed on each of the second conductivity type pillars provided at the edge of the active cell.

4. The super junction semiconductor device according to claim 3, further comprising:
source regions of the first conductivity type formed in the body region of the second conductivity type; and
a body contact region of the second conductivity type formed between the source regions of the first conductivity type.

5. The super junction semiconductor device according to claim 1, further comprising:
at least one pillar of the second conductivity type provided at an outermost portion of the edge termination region and not connected to the charge sharing region.

6. The super junction semiconductor device according to claim 4, further comprising:
a field oxide film formed on the charge sharing region in the edge termination region; and
a gate insulating film formed on the source regions and the plurality of first conductivity type pillars in the active cell, an end portion and a side surface of the field oxide film toward the peripheral region, and the charge sharing region at an edge of the peripheral region.

7. The super junction semiconductor device according to claim 6, further comprising:
a gate electrode formed on the gate insulating film in the active cell;
a field plate formed on the gate insulating film formed over the peripheral region and the edge termination region;
a first insulating film formed on side surfaces and an upper surface of the gate electrode, the field plate, and the field oxide film;
a second insulating film formed on the first insulating film; and
a gate runner formed on the field plate and connected to the field plate.

8. The super junction semiconductor device according to claim 2, further comprising:
a peripheral contact region formed in the peripheral charge sharing region disposed in the peripheral region;
a source electrode formed on a body contact region formed between source regions of the active cell and the peripheral contact region of the peripheral region; and
a drain electrode formed under the substrate.

9. The super junction semiconductor device according to claim 8, wherein a length of a cross-sectional area of the peripheral contact region is determined according to a preset ratio based on a length of a cross-sectional area of the charge sharing region in the peripheral region.

10. The super junction semiconductor device according to claim 1, wherein, when the super junction semiconductor device is viewed from above, an area where an upper surface and a lower surface of the peripheral region and side surfaces of the peripheral region meet is defined as a peripheral corner region, and an area of the charge sharing region in the peripheral corner region is determined according to a preset ratio based on an area of the peripheral corner region.

11. The super junction semiconductor device according to claim 2, wherein a second conductivity type concentration increases at a point where the peripheral charge sharing region meets the edge termination charge sharing region and diffuses further toward the second conductivity type pillars.

12. The super junction semiconductor device according to claim 2, wherein a depth of the peripheral charge sharing region is greater than a depth of the edge termination charge sharing region.

13. The super junction semiconductor device according to claim 8, wherein a length of a cross-sectional area of the peripheral contact region accounts for 30 to 60% of a length of a cross-sectional area of the peripheral charge sharing region.

14. The super junction semiconductor device according to claim 10, wherein an area of the charge sharing region in the peripheral corner region accounts for 30 to 80% of the area of the peripheral corner region.

15. The super junction semiconductor device according to claim 10, wherein a horizontal length of the charge sharing region in the peripheral corner region accounts for 20 to 50% of a horizontal length of the peripheral corner region.

16. A method of manufacturing a super junction semiconductor device, the method comprising:
forming an epitaxial layer in which first conductivity type pillars and second conductivity type pillars are alternately formed at an edge of an active cell and in a peripheral region and an edge termination region of a semiconductor substrate;
forming an edge termination charge sharing region connecting the second conductivity type pillars formed above the epitaxial layer in the edge termination region;
forming a field oxide film on the edge termination charge sharing region and the epitaxial layer in the edge termination region;
forming a gate insulating film on both ends of the field oxide film and on the first conductivity type pillars in the active cell;
forming a gate electrode on the gate insulating film in the active cell and forming a field plate on the gate insulating film in the edge termination region;
forming a body region on the second conductivity type pillars in the active cell;
forming a peripheral charge sharing region connecting the second conductivity type pillars formed above the epitaxial layer in the peripheral region;
forming source regions in both ends of an upper portion of the body region;
forming a first insulating film over an entire region of the semiconductor substrate;
forming a body contact region between the source regions in the body region and forming a peripheral contact region on top of the peripheral charge sharing region;
forming a second insulating film on the first insulating film;
forming a source electrode connected to the body contact region and the peripheral contact region, and forming a gate runner connected to the field plate; and
forming a drain electrode under the semiconductor substrate.

17. The method according to claim 16, wherein the forming of the epitaxial layer includes:
forming a first epitaxial layer having a predetermined height on the semiconductor substrate at the edge of the active cell and in the peripheral region and the edge termination region;
implanting second conductivity type ions into a portion in which the second conductivity type pillars are formed above the first epitaxial layer;
diffusing the second conductivity type ions while forming a second epitaxial layer on the first epitaxial layer; and
implanting the second conductivity type ions into a portion in which the second conductivity type pillars are formed above the second epitaxial layer.

18. The method according to claim 17, further comprising:
forming a source contact region on the source regions;
forming a source electrode connected to the body contact region, the source contact region, and the peripheral contact region; and
forming a drain electrode beneath the substrate.

19. The method according to claim 16, wherein, when the super junction semiconductor device is viewed from above, an area where an upper surface and a lower surface of the peripheral region and side surfaces of the peripheral region meet is defined as a peripheral corner region, the forming of the peripheral charge sharing region further includes determining an area of the charge sharing region in the peripheral corner region according to a preset ratio based on an area of the peripheral corner region.

20. The method according to claim 16, wherein the forming of the edge termination charge sharing region further includes:
forming an edge charge sharing region mask on the epitaxial layer;
forming a plurality of openings by patterning the edge charge sharing region using the edge charge sharing region mask; and
forming a second conductivity type edge charge sharing ion implantation layer on the plurality of openings, and
wherein a width of the second conductivity type edge charge sharing ion implantation layer gradually increases from the edge termination region toward the peripheral region.
